(19) United States
(12) Patent Application Publication
(10) Pub. No.: US 2012/0220071 A1
(43) Pub. Date: Aug. 30, 2012

(54) SCREEN MASK AND MANUFACTURING METHOD OF A SOLAR CELL USING THE SCREEN MASK

(76) Inventors: Young-Su Kim, Yongin-si (KR); Doo-Youl Lee, Yongin-si (KR); Sung-Chul Lee, Yongin-si (KR)

(21) Appl. No.: 13/299,173

(22) Filed: Nov. 17, 2011

(30) Foreign Application Priority Data
Feb. 24, 2011 (KR) 10-2011-0016547

(51) Int. Cl. H01L 31/18; B05C 17/06

(52) U.S. Cl. 438/98; 101/123; 257/E31.124

(57) ABSTRACT

A screen mask has a mesh, a frame, and at least one emulsion pattern. The mesh includes a squeeze surface pressed by a squeegee, and a discharge surface discharging a paste. The frame fixes an edge of the mesh. The emulsion pattern is placed on the discharge surface and includes a main pattern, and an auxiliary pattern spaced apart from the main pattern.

### CROSS-REFERENCE TO RELATED APPLICATION

This application claims priority to and the benefit of Korean Patent Application No. 10-2011-0016547, filed in the Korean Intellectual Property Office on Feb. 24, 2011, the entire content of which is incorporated herein by reference.

### BACKGROUND

1. Field

The described technology relates generally to a screen mask and screen printing process using the screen mask, and more particularly to a method of manufacturing a solar cell on which a pattern is formed.

2. Description of Related Technology

A solar cell is manufactured by forming p-doped and n-doped regions on a silicon substrate. When the solar energy from sunlight is irradiated onto a p-n junction, electron-hole pairs are produced, and the electrons are gathered at the n-doped region whereas the holes are gathered at the p-doped region. With photovoltaic effect caused by the movements of electrons and holes, potential difference is created between opposing ends of the p-n junction. Here, electrons and holes move to the n-doped regions and p-doped regions, respectively, such that current is generated. Electricity, derived by the combination of the potential difference and the current, is provided to a load circuit, connected to the solar cell. As such, solar energy is converted to electrical energy.

FIG. 1A is a schematic perspective view of a back contact solar cell, and FIG. 1B is a schematic cross-sectional view taken along line I-I′ of FIG. 1A. The solar cell 10 includes a substrate 410, a light absorption layer 412, p-doped regions 422, n-doped regions 424, a passivation layer 428, and contact electrodes 429. The substrate 410 is a wafer or a board, including single crystal silicon or poly crystal silicon, and functions as a passage for electrons and holes. The light absorption layer 412, including silicon nitride and/or silicon nitride oxide, is disposed on a textured front surface 413 whereas p-doped and n-doped regions 422 and 424, are alternatively disposed in a back surface 414 of the substrate 410. The passivation layer 428, including silicon oxide, is disposed on the back surface 414 of the substrate 410. The passivation layer 428 includes a plurality of via holes 440, formed by elimination of parts of the passivation layer 428, through which the doped regions 422 and 424 and contact electrodes 429 are connected to each other.

The doped regions 422 and 424 and via holes 440 are formed by either a photolithography process, a chemical vapor deposition (“CVD”) process, or a screen printing process. Among the processes, the photolithography process and the CVD process include complex steps at high economic cost. Accordingly, there is a need to form these doped regions 422 and 424 and via holes 440 with simple steps at low economic cost.

The screen printing process is a method of forming wirings and/or patterns, such as doped regions, via holes, and/or contact electrodes, with simple steps at low economic costs. However, due to spread of a paste used in the screen printing process, it is difficult to make a narrow width circular or linear, pattern or wiring, which is a desired width for a pattern or wiring on a workpiece. For example, narrowing a width of a via hole to less than 200 μm is difficult.

An efficiency of a solar cell is improved either as width of the doped region and/or via hole gets narrower, or as a distance between a doped regions and/or via holes gets shorter due to the reduction of electron-hole recombination or bulk resistance of the silicon substrate. For narrowing such width and/or distance, a hot melt method has been introduced. The hot melt method includes a heating step and a discharging step. The heating step includes heating a screen mask by supplying electricity thereto such that a temperature of the screen mask is higher than a temperature of a workpiece. The discharging step includes discharging a paste from the screen mask to the workpiece. The hot melt method, however, uses extra equipments for the heating step, may not be safe, and needs development of special expensive paste to be used for the method. Accordingly, there is a need to provide a screen printing process that can be performed with simple equipments, high safety, and low cost.

The above information disclosed in this Background section is only for enhancement of understanding of the background of the invention and therefore it may contain information that does not form the prior art that is already known in this country to a person of ordinary skill in the art.

### SUMMARY

An aspect of an embodiment of the described technology is directed toward a manufacturing method of a solar cell with simple process and low cost. Another aspect of an embodiment of the described technology is directed toward a solar cell including narrow wirings and patterns. Still another aspect of an embodiment of the described technology is directed to a screen mask, which is used in manufacturing of a solar cell including narrow wirings and patterns.

According to one exemplary embodiment, a screen mask used in forming a desired pattern on a workpiece includes a mesh including a squeeze surface and a discharge surface facing the squeeze surface, a frame fixing an edge of the mesh, and at least one emulsion pattern placed on the discharge surface of the mesh. The squeeze surface is suppressed by a squeegee and the discharge surface discharges a paste. The emulsion pattern includes a main pattern and an auxiliary pattern. The main pattern is shaped substantially the same as the desired pattern, which is to be formed on the workpiece. The auxiliary pattern is spaced apart from the main pattern, whereby the paste is spread on the workpiece and toward under the auxiliary pattern of the emulsion pattern. The mesh includes a plurality of horizontal wires extending horizontally, a plurality of vertical wires extending vertically and perpendicularly interlaced with the horizontal wires, and an opening formed by a pair of the horizontal wires and a pair of the vertical wires. The emulsion pattern includes a pattern gap located between the main pattern and the auxiliary pattern. The width of the pattern gap is smaller than the width (e.g., a diameter) of the opening.

According to one exemplary embodiment, the width of the pattern gap is equal to or larger than about 32 percent of the width of the opening of the mesh.

According to another exemplary embodiment, the width of the pattern gap is equal to or smaller than about 43 percent of the width of the opening of the mesh.

According to one exemplary embodiment, the main pattern and the auxiliary pattern of the emulsion pattern are circles, and the width of the main pattern is larger than the width of the pattern gap.

According to another exemplary embodiment, the emulsion pattern is a linear pattern extending in a first direction such that the linear pattern includes a mid-portion and an end-portion. The width of the pattern gap at the mid-portion is larger than the width of the pattern gap at the end-portion. The linear pattern includes a stem crossing and perpendicularly extending to the first direction, a branch extending parallel to the first direction, and a corner portion where the stem and the branch meet. The mid-portion and the end-portion are included in the branch. The width of the pattern gap at the corner portion of the linear pattern is larger than the width of the pattern gap at the mid-portion of the pattern gap.

According to another exemplary embodiment, at least one of the emulsion patterns is a circular pattern including a circular main pattern and a circular auxiliary pattern. Another at least one of the emulsion patterns is a linear pattern including a linear main pattern and a linear auxiliary pattern both extending in a common direction (i.e., the linear main pattern and the linear auxiliary pattern extending parallel with one another). A width of a pattern gap between the circular main pattern and the circular auxiliary pattern is smaller than a width of a pattern gap between the linear main pattern and the linear auxiliary pattern.

According to another exemplary embodiment, a width of the main pattern in a portion thereof is larger than the width of the desired pattern in a portion corresponding to the portion of the main pattern. The width of the main pattern is equal to or smaller than about 170 micrometers.

According to another exemplary embodiment, the emulsion pattern includes a linear pattern extending in a direction and including a mid-portion and an end-portion. The mid-portion includes the main pattern, and the end-portion includes the main pattern and the auxiliary pattern. The mid-portion further includes a second auxiliary pattern near an edge of the main pattern. The second auxiliary pattern of the mid-portion is partially broken.

According to one exemplary embodiment, a manufacturing method of a solar cell, which converts solar energy to electrical energy, includes placing a screen mask above a pattern surface of a silicon substrate, and moving a squeegee along a direction of the screen mask. For the placing of the screen mask, the screen mask is loaded with a paste on a squeeze surface, equipped with at least one emulsion pattern on a discharge surface opposing the squeeze surface, and equipped with a plurality of openings in a mesh formed between a plurality of horizontal wires extending horizontally and a plurality of vertical wires extending vertically and perpendicularly interlaced with the horizontal wires. In moving a squeegee, the paste passes the opening of the mesh and is discharged onto the pattern surface of the silicon substrate. The emulsion pattern comprises a main pattern and an auxiliary pattern spaced apart from the main pattern with a width of a pattern gap. The opening of the mesh is divided into an opening outside of the emulsion pattern and an opening within the pattern gap. An amount of discharged paste of a unit area is larger with a discharged paste discharged from the opening outside of the emulsion pattern on the mesh, than with a discharged paste discharged from the pattern gap of the emulsion pattern, whereby the paste is spread on the workpiece and toward under the auxiliary pattern of the emulsion pattern.

According to one exemplary embodiment, the silicon substrate includes at least one linear doped region and the emulsion pattern is disposed on the linear doped region. The doped region of the silicon substrate is formed by a screen printing process where a linear first emulsion pattern is used, the linear first emulsion pattern including a first main pattern and a first auxiliary pattern both extending in a common direction (i.e., the main pattern and the auxiliary pattern extending parallel with one another), the auxiliary pattern being spaced apart from the first main pattern with a width of a first pattern gap between the first main pattern and the first auxiliary pattern.

According to another exemplary embodiment, a second emulsion pattern is disposed on the doped region. The second emulsion pattern includes a circular second main pattern and a second auxiliary pattern spaced apart from the second main pattern with a width of a second pattern gap between the second main pattern and the second auxiliary pattern. The width of the first pattern gap is larger than the width of the second pattern gap. A via-hole, which connects the doped region to a contact electrode, is formed on the doped region, which is made by the first emulsion pattern. The contact electrode is exposed out of the solar cell and wherein a width of the via-hole is equal to or smaller than about 150 micrometers. The width of the pattern gap of the emulsion pattern is larger than the width of the via-hole.

According to one exemplary embodiment, a screen printing method, used in forming of a desired pattern onto a workpiece, includes placing a screen mask above a desired pattern forming surface of the workpiece and discharging the paste onto the desired pattern forming surface. The screen mask includes a squeeze surface loaded with a paste, and a discharge surface where at least one emulsion pattern is disposed thereon. The discharging of the paste onto the desired pattern forming surface is accomplished by compressing the paste on the squeeze surface, such that the paste is discharged from the discharge surface. The emulsion pattern includes a main pattern and an auxiliary pattern spaced apart from the main pattern with a pattern gap, and the paste passes through the pattern gap and is spread under the auxiliary pattern. In one embodiment, the paste is spread only under a portion of the main pattern of the emulsion pattern, and is spread under the entire area of the auxiliary pattern.

### BRIEF DESCRIPTION OF THE DRAWINGS

The patent or application file contains at least one drawing/image executed in color. Copies of this patent or patent application publication with color drawing(s)/image(s) will be provided by the Office upon request and payment of the necessary fee.

FIG. 1A is a schematic perspective view of a back contact solar cell.

FIG. 1B is a schematic cross-sectional view taken along line I-I′ of FIG. 1A.

FIG. 2A is a schematic perspective view of an exemplary embodiment of a screen mask.

FIG. 2B is a schematic enlarged partial plane view of the screen mask and an exemplary embodiment of an emulsion pattern thereof.

FIG. 3 is a schematic enlarged partial cross-sectional view of a workpiece and the screen mask under a screen printing process.

FIG. 4A is a schematic partial plane view of an exemplary embodiment of a mesh of a screen mask, which was used in an experiment.

FIG. 4B is a schematic partial plane view of an exemplary embodiment of an emulsion pattern, which was used in the experiment.

FIG. 4C is a table showing different pattern widths of the emulsion pattern, which were used in the experiment.

FIG. 4D is an enlarged picture of holes obtained from the screen printing process of the experiment.

FIG. 4E is a table showing diameters of the holes of FIG. 4D.

FIG. 5 is a schematic plane view of a linear pattern.

FIGS. 6A and 6B are schematic enlarged plane and cross-sectional views of an exemplary embodiment of a solar cell and a screen mask, in the forming of doped-regions of the solar cell.

FIGS. 6C and 6D are schematic enlarged plane and cross-sectional views of an exemplary embodiment of a solar cell and a screen mask, in the forming of via-holes of the solar cell.

FIGS. 7A to 7C are schematic plane views of exemplary embodiments of linear emulsion patterns, where an auxiliary pattern is disposed around a main pattern.

FIG. 8 is a schematic plane view of an exemplary embodiment of circular emulsion pattern, where a part of a pattern gap is covered by a bridge.

### DETAILED DESCRIPTION

With reference to the accompanying drawings, exemplary embodiments of the invention, in which a screen mask and partial features of various layers of a solar cell are included, will be described in detail. Like reference numerals may refer to the same elements, features, and/or structures in the drawings and the following description. While many features will be presented in the following description of embodiments, the figures shall not limit the scope of the invention described in the claims unless defined by the appended claims and their equivalents.

In the embodiments, a workpiece refers to an object, on which a desired pattern is printed by a screen printing method, and may be a solar cell and other apparatus or product. The desired pattern may be lines, recesses, and/or holes, to be formed on the workpiece.

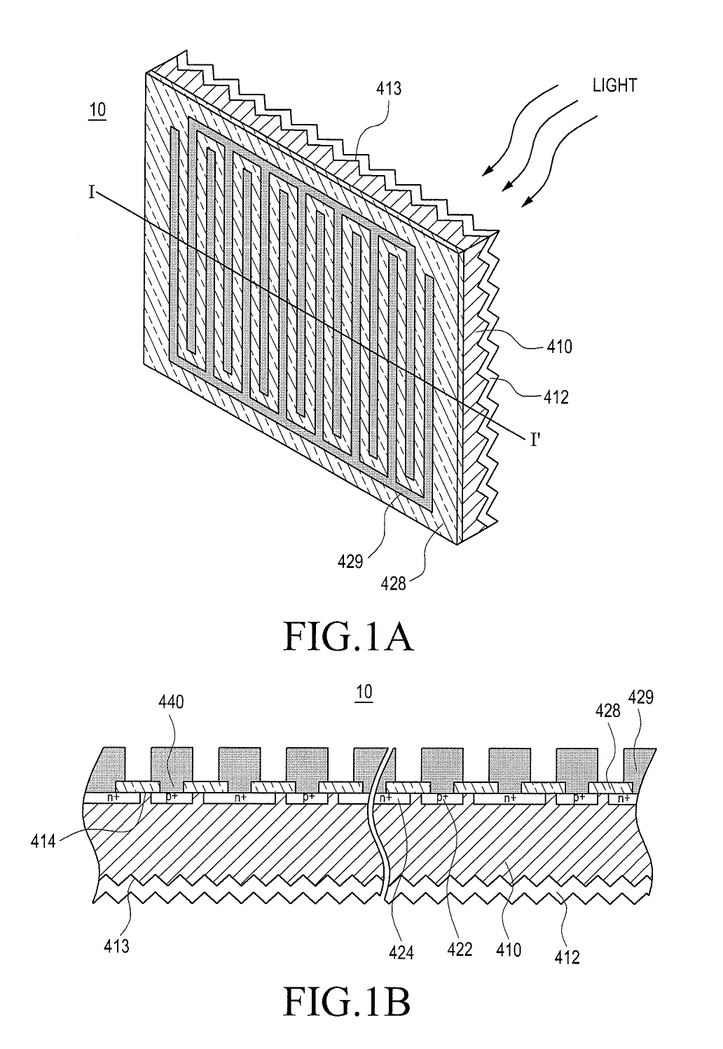

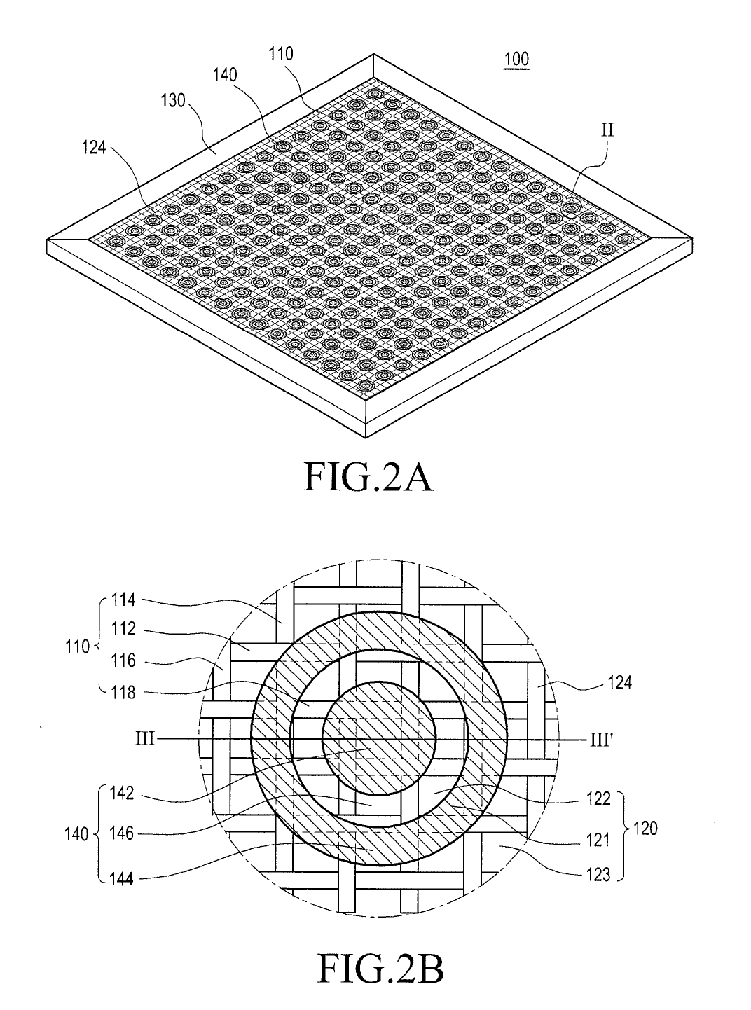

FIG. 2A is a schematic perspective view of a screen mask, used in a screen printing process, from which a recess of a layer of a solar cell is formed according to a exemplary embodiment of the invention. FIG. 2B is a schematic enlarged partial plane view enlarging the part II of FIG. 2A. The recess of one layer may be the via-hole shown in FIG. 1 B. A screen mask, according to one characteristics of the invention, includes an emulsion pattern, including a main pattern and an auxiliary pattern. The main pattern has a substantially similar shape and size with a desired pattern, and the auxiliary pattern is separated and spaced apart from the main pattern.

Referring to FIG. 2A, a screen mask 100, including a mesh 110, an emulsion pattern 140, and a frame 130, is disclosed. The mesh 110 includes horizontal wires and vertical wires, each of which horizontally and vertically extends, respectively, such that the horizontal and vertical wires are perpendicularly interlaced and make an opening where a paste passes through. The wires may include stainless steel and/or polyester, which has characteristics of elastic force capable of being suppressed (or pushed-down) by a squeegee or rebounding back when the squeegee is removed. On a discharge surface 124 of the mesh 110 are disposed emulsion patterns 140.

The emulsion patterns 140 are made through a series of steps including: a step of forming an emulsion layer, including a mixture of PVA (polyvinyl alcohol), PVAC (polyvinyl acetate), diazo compound, and water, on an entire area of the discharge surface; a step of exposing the emulsion layer in a set or predetermined shape to a light; a step of etching the exposed emulsion layer; and a step of curing the un-exposed portion of the emulsion layer. The emulsion pattern 140 allows the paste to be disposed on a desired area in a desired amount on an area of the workpiece by prohibiting discharge of the paste where the opening of the mesh 10 is blocked by the emulsion pattern 140. In the vicinity of edges of the mesh 110 is disposed a frame 130 such that the mesh maintains a constant tension.

Referring to FIG. 2B, a enlarged plane view of portion II of FIG. 2A, where both one emulsion pattern and a portion of the mesh around the emulsion pattern are illustrated in detail, is shown. The emulsion pattern 140 includes a main pattern 142 whose shape and size are similar to the shape and size of the desired pattern, an auxiliary pattern 144 which is apart from but close to the main pattern 142, and a pattern gap 146, which is an area (or a gap) between the main pattern 142 and the auxiliary pattern 144.

The emulsion pattern 140 is disposed on a discharge surface 124. The main pattern 142 and the auxiliary pattern 144 of the emulsion pattern 140 cover parts of the horizontal wires 112, the vertical wires 114, and the opening 120 of the mesh 110. The paste moves from the squeegee surface to the discharge surface 124 by passing through the opening 120 and eventually is discharged onto the workpiece. In the mean time, a portion of the paste does not pass through the opening 121, which is covered by the emulsion pattern 140. The paste has a viscosity to pass through the opening of the mesh easily. Due to such viscosity, the paste, disposed on the workpiece, shows spread phenomenon, in which the paste flows from the disposed area to the peripheral area of the disposed area. Due to of the spread phenomenon, a portion of the paste is disposed under edges of the main and auxiliary patterns 142 and 144 of the emulsion pattern 140.

An intensity of the spread phenomenon is proportional to the amount and viscosity of the disposed paste on the workpiece. Since the amount of the disposed paste is proportional to the size of the opening of the mesh, if the size of the area of the opened opening of the mesh is controlled, the size of the paste area can be controlled. Referring to FIG. 2B, since the area of the opening 122 in the pattern gap 146 of the emulsion pattern 140 is smaller than the area of the opening 123 outside the emulsion pattern 140, the spread area of the disposed paste passing through the opening 122 in the pattern gap is smaller than the spread area of the disposed paste passing through the opening 123 outside the emulsion pattern 140.

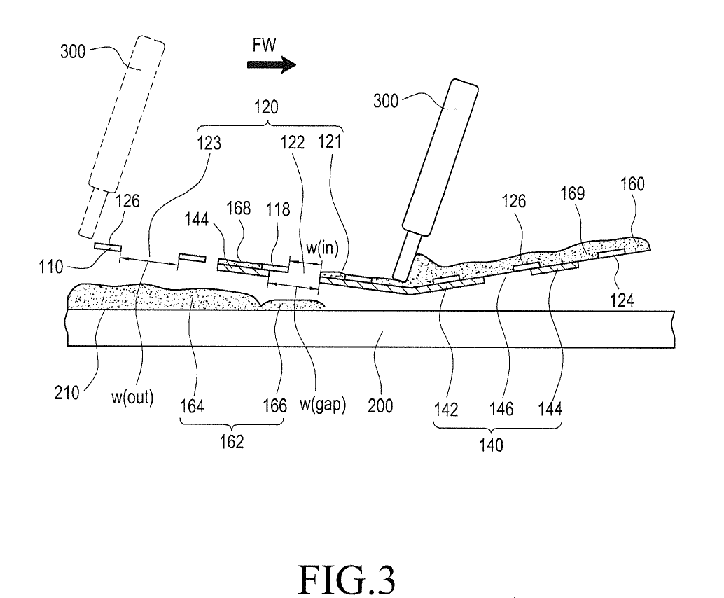

Referring to FIG. 3, a cross-sectional view, cut along line III-III′ of FIG. 2B, is disclosed when a paste passes through the opening 122 in the pattern gap 146 of the emulsion pattern 140 and the opening 123 outside the emulsion pattern 140. A screen printing process is divided into a paste disposing step and a squeezing step. The paste disposing step involves disposing the paste 160 onto the squeegee surface 126 of the mesh 110 with a constant thickness thereof. The squeezing step involves pressing the paste loaded squeegee surface to the workpiece with a squeegee or a roller, which moves in one direction FW as shown in FIG. 3.

A pre-discharge paste 169, which is not yet pressed by squeegee 300, is eventually discharged onto a print surface 210 of the workpiece 200 by passing through the opening 120 of the mesh 110. As disclosed above, a portion of the opening 121 is covered by an emulsion pattern 140, and the paste remains thereon. If one opening is partially covered by the emulsion pattern 140, then the paste is discharged through the uncovered part 122 of the opening.

Referring to FIG. 3, a width w(out) of an opening 123 outside of the emulsion pattern 140 is larger than a width w(in) of an opening 122 in the pattern gap 146 where a paste can pass through. Accordingly, the amount of the paste 164 discharged from outside of the emulsion pattern 140 is more than the amount of the paste 166 discharged from the pattern gap 146 of the emulsion pattern 140, and the edges of the discharged paste 164 is spread under the auxiliary pattern 144. Since the paste 166, which is discharged from the pattern gap 146, is relatively less in amount, the paste 166 is less spread out than the paste 164, discharged from the opening 123 outside the emulsion pattern 140. As such, the paste 166 discharged from the pattern gap 146 narrowly spreads toward the main pattern 142 and the auxiliary pattern 144. Because the main pattern 142 and the desired pattern have substantially similar shapes and sizes, the small amount of the paste 166, discharged from the pattern gap 146, does not excessively spread out under the main pattern 142. However, if the paste 166, discharged from the pattern gap 146, is spread too narrowly, the paste 166 might not spread under the auxiliary pattern 144; therefore, it is required that the width of the auxiliary pattern 144 is set to make the pastes 164 and 166 spread under the entire area of the auxiliary pattern 144. In addition, the widths and sizes of the opening 120, the pattern gap 146, and the auxiliary pattern 144 are required to be controlled to make the paste 166 that is discharged from the pattern gap 146, spread under the inner area of the main pattern without deterioration of the size of the desired pattern.

If the size of the opening 121, covered by the emulsion pattern 140, is narrowed and the width w(gap) of the pattern gap 146 becomes larger than the width of the opening 120 of the mesh 110, the amount of discharged paste 166 passing through the opening 122 in the pattern gap 146 gets larger and spreads excessively under the main pattern 142, such that the shape of the printed pattern on the print surface 210 of the workpiece 200 becomes different from the desired pattern due to an error of breaking a line and/or filling a hole or recess. Hence, the width of the pattern gap 146 should be narrower than the width of the opening 120 of the mesh 110.

In one embodiment, the open ratio of the opening 122 in the pattern gap 146 is smaller than the open ratio of the opening 123 outside the emulsion pattern 140 since the opening 122 in the pattern gap 146 is partly covered by a main pattern 142 and/or an auxiliary pattern 144. The open ratio is the percent that the uncovered area of the opening is divided by a reference area such as an area of the pattern gap 146 or an outside area from the emulsion pattern 140.

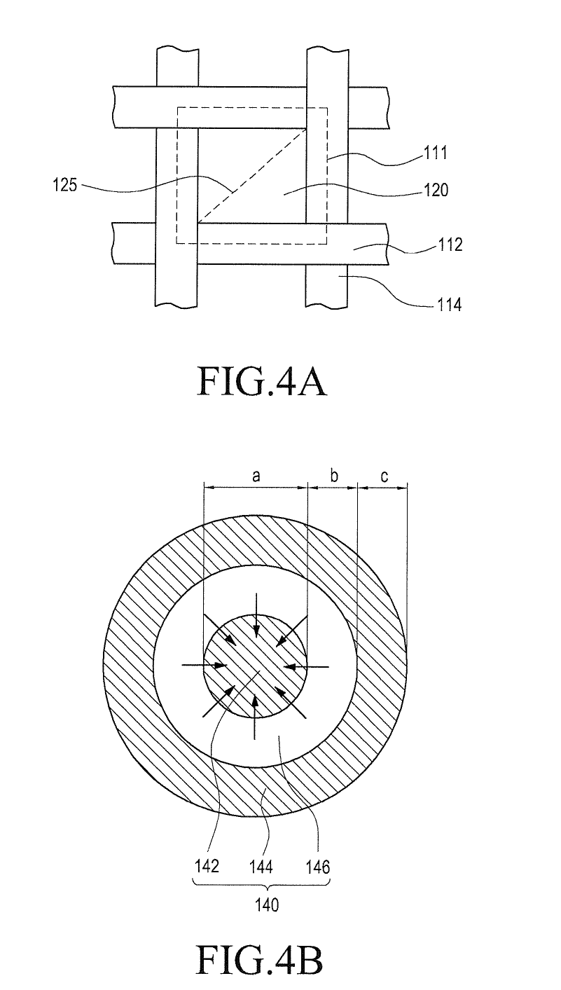

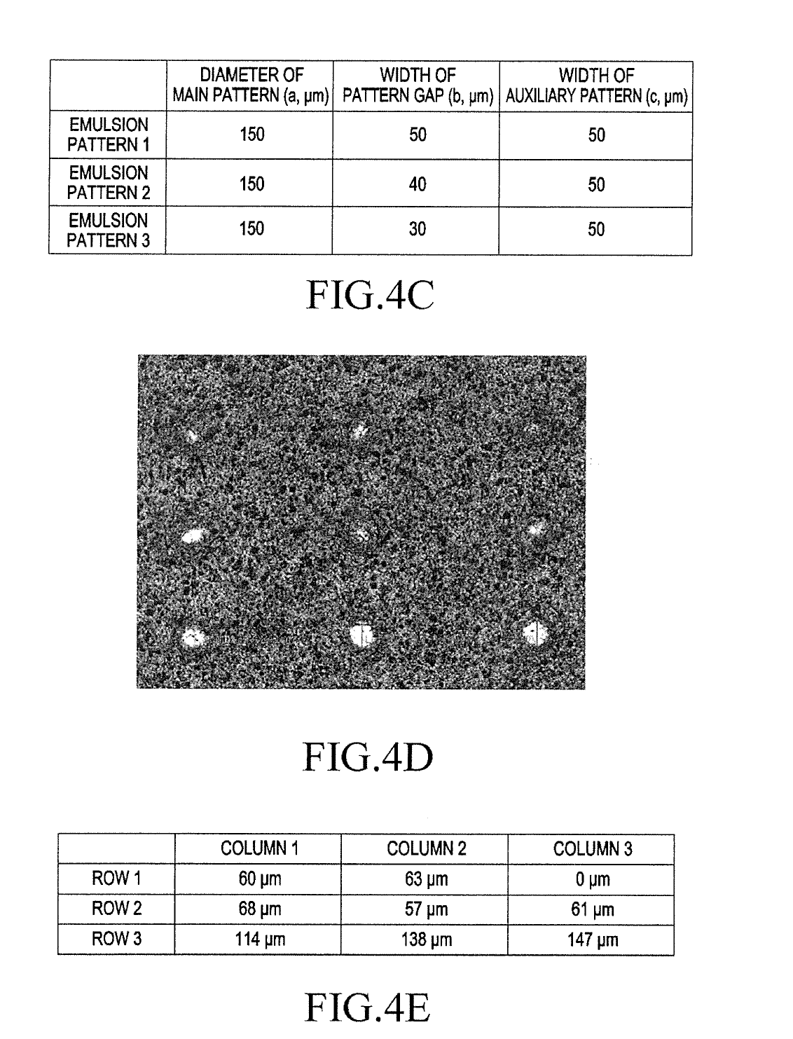

To find out the aforesaid critical or appropriate pattern gap, experiments of measuring diameters of holes, where various pattern gaps had different widths, were made. Referring to FIG. 4A, a schematic partial plane view of a mesh of a screen mask, used in the experiments is disclosed. The mesh was SUS280-25, model number of Samborn Screen, and included stainless steel wires. The mesh 110 had a group of horizontal and vertical wires 112 and 114, where 280 wires of 25 μm thick were allocated in one inch of horizontal and/or vertical directions, such that the wires 112 and 114 were distributed constantly along the entirety of the mesh 110. The distance between adjacent wires was 66 μm according to a calculation of dividing 2.54 cm (one inch) with 280 and subtracting the thickness of one wire therefrom, (((2.54 cm/280)−25 μm). The open ratio was the ratio of an area of an opening 120 to an area of an unit mesh 111, defined by both a pair of horizontal wires and a pair of vertical wires and expressed in dotted lines, ((66 μm)²/(91 μm)²×100). The calculated open ratio was 53 percent.

Referring to FIG. 4B, a schematic partial plane view of the emulsion pattern is disclosed. As disclosed above, an emulsion pattern is formed from an emulsion, a mixture of PVA, PVAC, diazo compound, and water; the emulsion is deposited, is exposed to light, is etched, and is cured to finally become an emulsion pattern, disposed on a discharge surface of a mesh. Generally, a diameter of a via-hole adopted in a solar cell is about 200 μm, and the diameter of the via-hole of the desired pattern was about 150 μm. Hence, the main pattern 142 of the emulsion pattern 140 was a circle with a diameter of 150 μm. In FIG. 4C, three different widths of the pattern gaps 146 were designed. That is, in FIG. 4C, a table shows diameters of three main patterns 142, widths of three pattern gaps 146, and widths of three auxiliary patterns 144 of three emulsion patterns 140. Here, as shown, the diameters of the main patterns 142 are constant (or are the same), and are each 150 μm. The widths of the auxiliary patterns 144 are also constant (or the same), and are each 50 μm. However, the widths of the patterns gaps 146 are shown to be different, and have the values of 30 μm, 40 μm, and 50 μm, respectively.

Referring to FIG. 4D, a picture of recesses of a paste, disposed on a workpiece by a screen printing process, is disclosed. The screen printing process used a screen mask whose emulsion patterns are shown in FIGS. 4A through 4C. Referring to FIG. 4E, a table showing diameters of the recesses of FIG. 4D is disclosed. Here, the recesses may be regarded as holes in light of forming a desired circular pattern on a workpiece. The conditions for the experiment of finding the effect of widths of pattern gaps to the diameters of the recesses, are listed in table 1 below.

TABLE 1

| | |
|---|---|
| Material of the paste | XZ-77 |
| | (Model number of ‘Sun Chemical’) |
| Viscosity of the paste | 50 dPa · s. (Desipascal second) |
| Thickness of the disposed paste | 20 μm |
| Thickness of the emulsion pattern | 10 μm |
| Size of the frame of the screen mask | 450 × 450 mm² |
| Clearance | 1.8 mm |
| Angle of the squeegee | 70 degrees |
| Speed of the squeegee | 100 mm/sec |
| Temperature | Room Temperature |

Since there are several distorted circles or ellipses among the recesses, the diameters of the recesses were measured in the vertical direction of FIG. 4D. In each row of FIG. 4D are recesses formed by a screen mask. The screen mask includes three emulsion patterns 1 at the top of the screen mask, three emulsion patterns 2 in the middle of the screen mask, and three emulsion patterns 3 at the bottom of the screen mask.

The recesses in the first row were formed by the paste, passing through the emulsion patterns 140 of the widest pattern gap 146, 50 μm. In this occasion, since the opening 122 in the pattern gap 146, discussed earlier in FIG. 3, is the widest, an excessive amount of paste was discharged to the workpiece by passing through the opening 120 of the mesh. Since the excessive amount of paste was spread under the main patterns 142, there was a case that no recess is formed on the workpiece. Specifically, paste was spread by a distance of 45 μm to 75 μm toward the mid-point of the main pattern 142 from every edge point of the main pattern 140, such that a space of a recess is easily filled with the paste.

The recesses in the second row were formed by the paste, passing through the emulsion patterns 140 whose pattern gaps 146 are 40 μm wide. In this occasion, since the discharged amount of the paste is less than the discharged amount of the paste, passing through the pattern gap 146 of width of 50 μm, the diameters of the recesses, not covered by the paste, were larger than the diameters of the recesses in the first row. Specifically, paste was spread by a distance of 30 μm to 40 μm toward inside of the main pattern 142 from every edge point of the main pattern 142. The three diameters of the recesses were measured to be from 57 μm to 68 μm, which shows that they did not vary much. Accordingly, the pattern gap, of 40 μm width, was regarded as a meaningful critical value under the experiment conditions presented above.

The recesses in the third row were formed by the paste, passing through the emulsion patterns 140 whose pattern gaps 146 are 30 μm. In this occasion, openings 122 in the pattern gap are the narrowest among the openings of the pattern gaps 146 used in the experiment. The paste was spread by a distance of 0 μm to 20 μm toward inside of the main pattern 142 from every edge point of the main pattern 142.

Therefore, in addition to the consideration of the spread of the paste under the main pattern, consideration of the spread of the paste under the auxiliary pattern was required to make the recesses have similar shapes and sizes of the desired patterns. In other words, when the paste is spread enough from the edge of the pattern gap toward inside of the auxiliary pattern, recesses have similar shape and size with the desired pattern by not having uncovered area with the paste under the auxiliary pattern. For example, the diameter of 147 μm of the recess shown in FIG. 4E is almost the same with the diameter of the desired pattern where spread of the paste is limited, e.g. small, and is not large toward the auxiliary pattern. If the width of the pattern gap is less than 30 μm, empty space might exist near the recess because of a deficiency of spread of the paste under the auxiliary pattern. Accordingly, it was regarded that the 30 μm width of pattern gap was a critical value under the experiment conditions presented above.

In an alternative exemplary embodiment, the diameter of the main pattern may be larger than the diameter of the desired pattern in connection with spread of the paste from the edges of the main pattern toward the inside thereof. For example, it will be understood by one skilled in the art that, as explained with pattern gap width of 30 μm, when the paste is spread from 0 μm to 20 μm, the diameter of the main pattern may be as wide as about 170 μm to obtain a desired 150 μm wide pattern.

As discussed with the explanation of FIG. 4A, the width of the opening 120 of the mesh was 66 μm, and the meaningful widths of the pattern gap 146 were the same or more than 30 μm and the same or less than 40 μm. Referring to FIGS. 2B and 3, the width w(in) of the opening 122 in the pattern gap 146 depends more on the length of the diagonal than the length of a side of the opening. Since the length of the diagonal was 93 μm (=66×2^{1/2} μm), it was derived by the present inventors that the appropriate width of the pattern gap 146 is the same or more than 32 percent (=(30 μm/93 μm)×100) and the same or less than 43 percent (=(40 μm/93 μm)×100), both of which are to the diagonal of the opening 120 of the mesh 110.

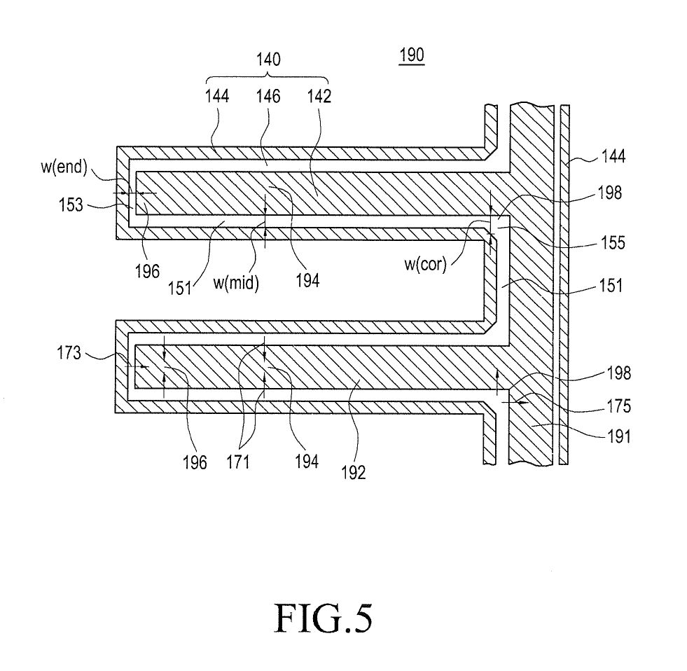

Aforesaid, the auxiliary pattern was explained to be a circular emulsion pattern, however, the auxiliary pattern can be applied to a linear emulsion pattern. Referring to FIG. 5, a linear emulsion pattern 140′, having auxiliary pattern for obtaining linear desired pattern, is disclosed. The linear emulsion pattern 190 may have a stem 191 and a branch 192 extruded and elongated from the stem 191. According to one embodiment of the invention, to make a linearly shaped pattern on a workpiece, the linear emulsion pattern 190 includes a main pattern 142′ and an auxiliary pattern 144′. The main pattern 142′ is an elongated line or a group of lines and similar in shape and size with the desired pattern. The auxiliary pattern 144′ is spaced apart from the main pattern 142′ with a width of a pattern gap 146′.

As disclosed above, a paste moves downwardly to be under the main pattern or the auxiliary pattern by passing through the pattern gap 146 during a screen printing process. When the circular emulsion pattern, shown in FIGS. 2B and 4B, is used, the paste concentrically moves from every edge point of the main pattern 142 toward the inside, a limited area, of the main pattern 142. In contrast, when a linear emulsion pattern, shown in FIG. 5, is used, the paste is distributed and moves from every edge point of the main pattern 142′ toward inside, which is extendedly elongated, of the main pattern. Hence, when a circular emulsion pattern and a linear emulsion pattern co-exist, the width of a pattern gap of the linear emulsion pattern can be wider than the width of a pattern gap of the circular emulsion pattern.

Widths of the pattern gap 146′ of the linear emulsion pattern 190 may vary according to the location of the pattern gap 146′ thereof. The widths of the pattern gap 146′ may be the narrowest at the end-portion 196 of the linear pattern 190, they may be the widest at a corner-portion 198 of the linear pattern 190, and they may be inbetween the other two widths at the mid-portion 194 of the linear pattern 190.

Specifically, a paste spread 171 under the main pattern 142′ in the mid-portion 194 of the linear pattern 190 occurs when the paste passes through the pattern gaps 151 adjacent to the two edges of the main pattern 142′. In contrast, at the end-portion 196 of the linear pattern 190, there exists a spread 171 of the paste, passing through pattern gaps 151 adjacent to the two long edges of the main pattern 142′, and the other spread 173 of the paste, passing through pattern gaps 153 adjacent the end-portion 196 of the linear pattern 190. If widths of two pattern gaps 151 and 153 are the same, the paste may excessively spread under main pattern 142′ at the end-portion 196 of the linear pattern 190, such that an error, in which the disposed paste on the workpiece is different with the desired pattern in shape and size, may occur. Accordingly, the width w(end) of the pattern gap 153 at the end-portion 196 of the linear pattern 190 may be narrower than the width w(mid) of the pattern gap 151 at the mid-portion 194 of the linear pattern 190.

Unlike the paste passing through the pattern gaps 151 and 153 at mid-portion 194 and the end-portion 196 of the linear pattern 190, a paste passing through a pattern gap 155 at the corner-portion 198 of the linear pattern 190 may be divided and move toward both under the stem 191 and under the branch 192 of the linear pattern gap 190. If appropriate amount of paste is required to be moved toward both under the stem 191 and under the branch 192 of the linear pattern 190, a wide pattern gap 155 at the corner-portion 198 of the linear pattern 190 should be provided. Accordingly, the width of the pattern gap 155 at the corner portion 198 of the linear pattern may be wider than the widths w(mid) and w(end) of the pattern gap 151 and 153 at the mid-portion 194 and the end-portion 196 of the linear pattern gap 190.

In an alternative embodiment, considering the spread 171 of the paste from the edge toward the middle point of the main pattern 142′, the width of the main pattern 142′ may be wider than the width of a part of the desired pattern, to which corresponds to the main pattern 142′ of the linear emulsion pattern 190.

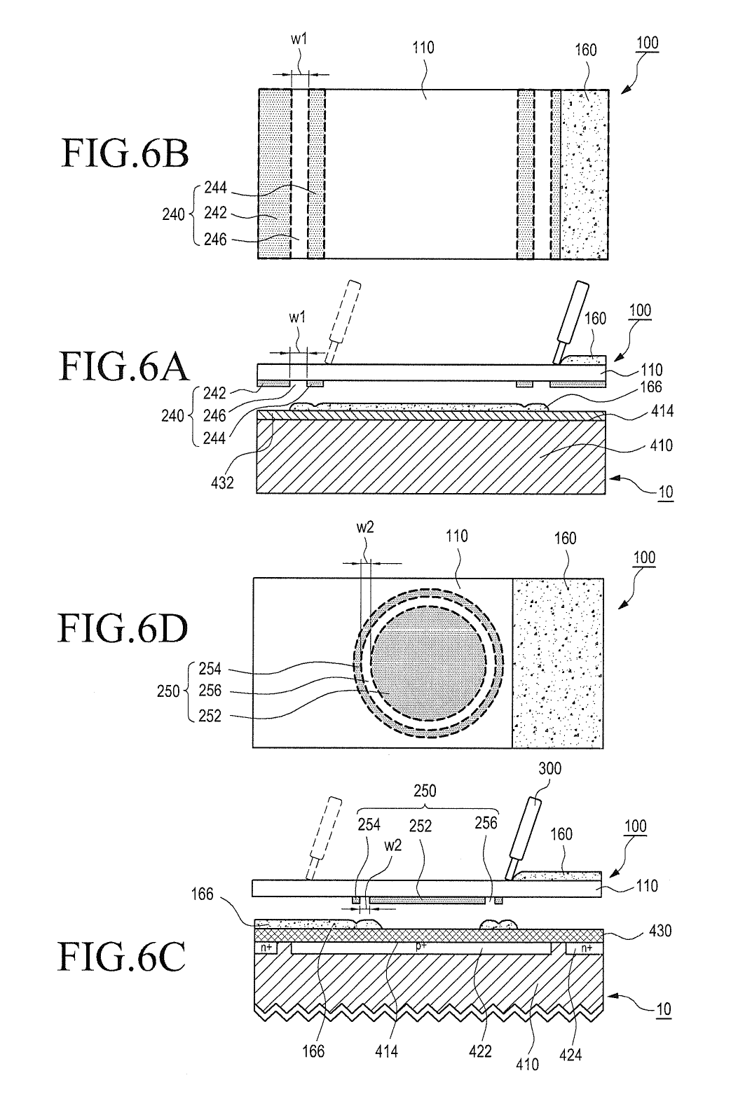

Referring to FIGS. 6A through 6D, schematic enlarged cross-sectional views and plane views of areas near the cross-sections of a solar cell are disclosed. The views in FIGS. 6A through 6D show that emulsion patterns, having auxiliary patterns, are used in the step of forming doped regions and via-holes thereon. More detailed manufacturing steps of back contact solar cell, such as forming n-doped regions or p-doped regions, or using the patterning method thereof, are disclosed aforesaid U.S. Pat. No. 6,998,288, published on Feb. 14, 2006 to David D. Smith, et al, and U.S. Pat. No. 7,388,147, published on Jan. 17, 2008 to William P. Mulligan, et al. In those publications, the n-doped regions are formed by diffusion from phosphorous doped silicon oxide or phosphorsilicate glass (PSG) to a silicon substrate, whereas p-doped regions are formed by diffusion from boron doped silicon oxide or borosilicate glass (BSG) to a silicon substrate.

As mentioned earlier, the n-doped and p-doped regions 422 and 424 are alternatively formed on a bottom surface 414 of the silicon substrate 410. For improvement of solar cell efficiency, the n-doped and p-doped regions 422 and 424 are required to be as narrow as possible, and the via-holes are required to be as small as possible and to be placed on one doped region as many as possible. Accordingly, the emulsion pattern with an auxiliary pattern may be proper for manufacturing a solar cell having narrow doped regions and via-holes.

FIG. 6A shows cross-sections of a solar cell 10 and a screen mask 100, which are under a step of forming doped regions on a back surface 414, pre-deposited with BSG 432, of the solar cell 10 by paste 160 dispensing where the paste passes through a first emulsion pattern 240. FIG. 6B is a schematic enlarged plane view of the screen mask 100, from which the screen mask near the cross-section is seen above. The first emulsion pattern 240 includes a first main pattern 242, a first auxiliary pattern 244 and a first pattern gap 246. The first emulsion pattern 240, as disclosed in FIG. 5, may have a longitudinal stem and a longitudinal branch. The pattern gaps 246 of the stem and/or the branch may be wider at a mid-portion thereof than an end-portion thereof. The plane view of the screen mask 100, depicted in FIGS. 6A and 6B, is the one from the mid-portion of the linear emulsion pattern, and a first width of the pattern gap 246 of the first emulsion pattern 240 is w1. The value of w1 is set to make the paste, which passes through the pattern gap 246 outer than the edges of the main pattern, is limitedly spread under the main pattern. More detailed explanation of the screen printing process is found in the explanation of the FIG. 3.

FIG. 6C shows cross-sections of a solar cell 10 and a screen mask 100, which are under the deposition step of a paste using a second emulsion pattern 250 onto a back surface 414, where n-doped and p-doped regions 424 and 422 are pre-formed and undoped silicate glass (USG) is pre-deposited thereon. FIG. 6D is a schematic enlarged plane view, from which the screen mask 100 near the crossed section, depicted in FIG. 6C, is seen above. The paste 160 used in the step of forming via-holes may be the same paste used in the step of forming doped regions. The second emulsion pattern 250 includes a second main pattern 252 and a second auxiliary pattern 254. The second emulsion pattern 250 is a circular pattern, as shown in FIG. 2B, and a second width thereof is w2. Unlike the spread of the paste in the linearly shaped doped region formation step, the spread of the paste in the via-hole formation step is the phenomenon that the paste 166 moves from every edge point toward the center of the main pattern 25. Therefore, the width w2 may be set to restrict the amount of paste that is spread. Specifically, the width w2 of the pattern gap 256 of the circular emulsion pattern 250 may be smaller than the width w1 of the pattern gap 246 of the linear emulsion pattern 240.

In FIGS. 6A through 6D, the formation of holes, recesses, patterns, and wirings of a bottom contact solar cell are disclosed and explained, however, embodiments of the invention, using emulsion patterns in the screen printing process, may be adapted for manufacturing other types of solar cells. For example, it will be well understood to one skilled in the art that an auxiliary pattern can be used in manufacturing various suitable kinds of solar cells such as a bulk silicon solar cell, where wirings are placed at both the front and the back surfaces of the solar cell, or a heterojunction intrinsic thin layer solar cell, where intrinsic silicon areas and electrodes are placed on both the front and the back surfaces of the solar cell. Here, the bulk silicon solar cell is disclosed in U.S. Pat. No. 2,780,765, published on Feb. 5, 1957 to Daryl M. Chapin, et al, and U.S. Pat. No. 5,705,828, published on Jan. 6, 1998 to Shigeru Noguchi, et al., the entire content of each of which is incorporated herein by reference.

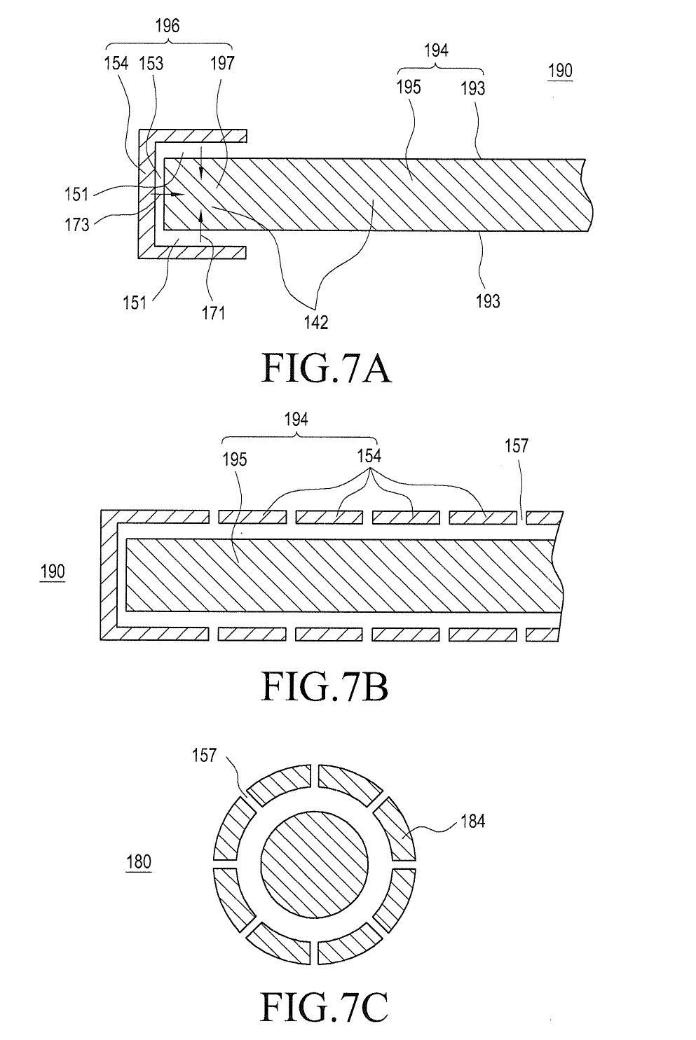

Aforesaid, embodiments of the invention are explained as the auxiliary pattern is disposed around the entire periphery of a main pattern; however, an auxiliary pattern may be partly disposed around the periphery of the main pattern. Referring to FIGS. 7A through 7C, emulsion patterns 180 and 190, where the auxiliary patterns 154 and 184 are partly disposed around the main pattern 142 and 195, are disclosed. A linear pattern 190 shown in FIG. 7A, includes an auxiliary pattern 154 at an end-portion 196 thereof, whereas no auxiliary pattern is disposed at a mid-portion 194 thereof. As discussed earlier in the explanation of FIG. 5, in screen printing process, at the end-portion 196 of the emulsion pattern 190, a paste is discharged from three pattern gaps 151 and 153, and spread of the paste is concentrated under the middle part of the main pattern 142′. In addition, as discussed with the explanation of FIGS. 3 through 4E, the width of the pattern gaps 151 and 153 at the end-portion 196 of the linear emulsion pattern 190 is shorter than the diagonal of the opening of the mesh.

Accordingly, the auxiliary pattern 154 is disposed around the main pattern 142′ and controls the amount of paste discharged under the main pattern 142′. Unlike the main pattern 197 at the end-portion 196 of the emulsion pattern 190, the main pattern 195 at the mid-portion 194 includes two elongated and extended edges 193. In the screen printing process, the paste, discharged from openings of the mesh adjacent to the edges 193, spreads under the main pattern 195 at the mid-portion 194 of the emulsion pattern 190 in a distributed manner along the whole edges 193 of the main pattern 195. Hence, the amount of paste, discharged at the periphery of the mid-portion 194, is controllable without auxiliary patterns.

In an alternative exemplary embodiment, as depicted in FIG. 7B, at the mid-portion 194 of the linear pattern 190, a partially broken line of auxiliary pattern 154 may be disposed. In a screen printing process, the amount of paste, passing through the mid-portion 194 of the linear pattern 190, is controllable by adjusting locations and/or lengths of the broken part 157 of the auxiliary pattern 154. If the broken part 157 is covered by one wire of a mesh in its entirety, there would be no paste passing through the broken part 157 of the auxiliary pattern 154; hence, the length of the broken part 157 may be longer than a width of one wire of the mesh.

In an alternative exemplary embodiment, as depicted in FIG. 7C, a circular emulsion pattern 180 may include a partially broken auxiliary pattern 184. In a screen printing process, an amount passing through the circular emulsion pattern 180 is controllable by adjusting locations and/or lengths of the broken part 187 of the auxiliary pattern 184. The broken auxiliary patterns 184 control the amount and size of the paste, disposed on the workpiece.

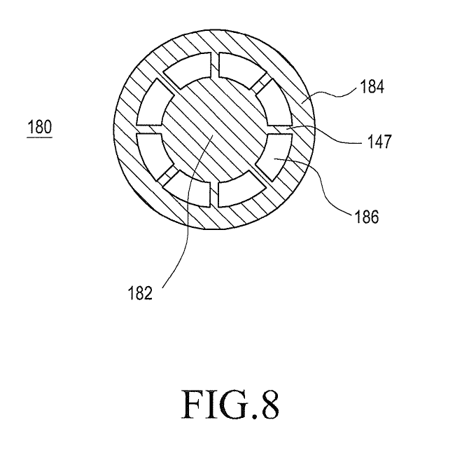

To control the amount of paste discharged on the workpiece, the auxiliary pattern and pattern gap may be designed differently from the earlier embodiments. Referring to FIG. 8, a circular pattern 180, where part of the pattern gap 186 is covered by a bridge 147, is disclosed. The main and auxiliary patterns 182 and 184 of the circular emulsion pattern 180 are interconnected by a bridge 147 formed in the pattern gap 186, and the bridge 147 prohibits or blocks the discharge of the paste onto the workpiece. Accordingly, the amount of paste, passing through the circular emulsion pattern 180, is controllable by adjusting location, width and size of the bridge 147. Even though not illustrated, it will be well understood by a skilled person in the art that a combination of a broken part of an auxiliary pattern and a bridge in a pattern gap may be possible in one emulsion pattern.

While the invention has been described in connection with certain exemplary embodiments, it is to be understood by those skilled in the art that the invention is not limited to the disclosed embodiments, but, on the contrary, is intended to cover various modifications included within the spirit and scope of the appended claims and equivalents thereof.

What is claimed is:

1. A screen mask used in forming a desired pattern on a workpiece, comprising:
a mesh comprising a squeeze surface and a discharge surface facing the squeeze surface, the squeeze surface being configured to be suppressed by a squeegee and the discharge surface being configured to discharge a paste;
a frame fixing an edge of the mesh; and
at least one emulsion pattern placed on the discharge surface of the mesh,
wherein the emulsion pattern comprises a main pattern and an auxiliary pattern, the main pattern is shaped substantially the same as the desired pattern to be formed on the workpiece, the auxiliary pattern is spaced apart from the main pattern, and the emulsion pattern is configured with the mesh to spread the paste on the workpiece and toward under the auxiliary pattern of the emulsion pattern.

2. The screen mask of claim 1, wherein the mesh comprises a plurality of horizontal wires extending horizontally, a plurality of vertical wires extending vertically and perpendicularly interlaced with the horizontal wires, and has an opening formed by a pair of the horizontal wires and a pair of the vertical wires,
wherein the emulsion pattern includes a pattern gap located between the main pattern and the auxiliary pattern, and a width of the pattern gap is smaller than a width of the opening.

3. The screen mask of claim 2, wherein the width of the pattern gap is equal to or larger than about 32 percent of the width of the opening of the mesh.

4. The screen mask of claim 2, wherein the width of the pattern gap is equal to or smaller than about 43 percent of the width of the opening of the mesh.

5. The screen mask of claim 1, wherein the main pattern and the auxiliary pattern of the emulsion pattern are circles, and a width of the main pattern is larger than that of a pattern gap between the main pattern and the auxiliary pattern.

6. The screen mask of claim 1, wherein the emulsion pattern is a linear pattern extending in a first direction such that the linear pattern comprises a mid-portion and an end-portion, and a width of a pattern gap between the main pattern and the auxiliary pattern at the mid-portion is larger than a width of the pattern gap between the main pattern and the auxiliary pattern at the end-portion.

7. The screen mask of claim 6, wherein the linear pattern comprises a stem crossing and perpendicularly extending to the first direction, a branch extending parallel to the first direction, and a corner portion where the stem and the branch meet, wherein the mid-portion and the end-portion are included in the branch, and wherein a width of the pattern gap between the main pattern and the auxiliary pattern at the corner portion of the linear pattern is larger than that of the pattern gap between the main pattern and the auxiliary pattern at the mid-portion of the linear pattern.

8. The screen mask of claim 1, wherein at least one of the emulsion patterns comprises a circular pattern including a circular main pattern and a circular auxiliary pattern, a linear pattern including a linear main pattern and a linear auxiliary pattern both extending in a common direction, and a width of a pattern gap between the circular main pattern and the circular auxiliary pattern is smaller than that of a pattern gap between the linear main pattern and the linear auxiliary pattern.

9. The screen mask of claim 1, wherein a width of the main pattern in a portion thereof is larger than that of the desired pattern in a portion corresponding to the portion of the main pattern.

10. The screen mask of claim 9, wherein the width of the main pattern is equal to or smaller than about 170 micrometers.

11. The screen mask of claim 1, wherein the emulsion pattern comprises a linear pattern extending in a direction and including a mid-portion and an end-portion, and wherein the mid-portion includes the main pattern, the end-portion includes the main pattern and the auxiliary pattern.

12. The screen mask of claim 11, wherein the mid-portion further comprises a second auxiliary pattern near an edge of the main pattern.

13. The screen mask of claim 12, wherein the second auxiliary pattern of the mid-portion is partially broken.

14. A method of manufacturing a solar cell for converting solar energy to electrical energy, the method comprising:
loading a paste on a squeeze surface, equipped with at least one emulsion pattern on a discharge surface opposing the squeeze surface, and equipped with a plurality of openings in a mesh formed between a plurality of horizontal wires extending horizontally and a plurality of vertical wires extending vertically and perpendicularly interlaced with the horizontal wires; and
moving a squeegee along a direction of a screen mask, such that the paste passes through the opening of the mesh and is discharged onto a pattern surface of a silicon substrate,
wherein the emulsion pattern comprises a main pattern and an auxiliary pattern spaced apart from the main pattern with a pattern gap, wherein the opening of the mesh is divided into an opening outside of the emulsion pattern and an opening within the pattern gap, wherein an amount of discharged paste for a unit area is controlled such that an amount of the paste passing through the opening of the mesh outside the emulsion pattern is greater than that of the paste passing through the opening within the pattern gap of the emulsion pattern, and wherein the paste is spread on a workpiece and toward under the auxiliary pattern of the emulsion pattern.

15. The method of manufacturing of claim 14, wherein the silicon substrate comprises at least one linear doped region, and the emulsion pattern is disposed on the linear doped region.

16. The method of manufacturing of claim 15, wherein the doped region of the silicon substrate is formed by a screen printing process, and the emulsion pattern comprises a linear first emulsion pattern used in the screen printing process, the linear first emulsion pattern comprising a first main pattern and a first auxiliary pattern both extending in a common direction, the first auxiliary pattern being spaced apart from the first main pattern with a first pattern gap between the first main pattern and the first auxiliary pattern.

17. The method of manufacturing of claim 16, wherein a second emulsion pattern is disposed on the doped region, the second emulsion pattern includes a circular second main pattern and a second auxiliary pattern spaced apart from the second main pattern with a second pattern gap between the second main pattern and the second auxiliary pattern.

18. The method of manufacturing of claim 17, wherein the width of the first pattern gap is larger than the width of the second pattern gap.

19. The method of manufacturing of claim 15, wherein a via-hole connecting the doped region to a contact electrode is formed on the doped region, which is made by the emulsion pattern, wherein the contact electrode is exposed out of the solar cell, and wherein a width of the via-hole is equal to or smaller than about 150 micrometers.

20. The method of manufacturing of claim 19, wherein the width of the pattern gap of the emulsion pattern is larger than that of the via-hole.

21. A screen printing method used in forming of a desired pattern onto a workpiece, the method comprising:
placing a screen mask above a desired pattern forming surface of the workpiece, the screen mask including a squeeze surface loaded with a paste, and a discharge surface where at least one emulsion pattern is disposed thereon; and
discharging the paste onto the desired pattern forming surface by pressing the paste on the squeeze surface, such that the paste is discharged from the discharge surface,
wherein the emulsion pattern comprises a main pattern and an auxiliary pattern spaced apart from the main pattern with a pattern gap, and wherein the paste passes through the pattern gap and is spread under the auxiliary pattern.

22. The screen printing process of claim 21, wherein the paste is spread under a portion of the main pattern of the emulsion pattern.

23. The screen printing process of claim 22, wherein the paste is spread under the entire area of the auxiliary pattern.
